(19) United States
(12) Patent Application Publication
(10) Pub. No.: US 2013/0241663 A1
(43) Pub. Date: Sep. 19, 2013

(54) PULSE WIDTH MODULATION SCHEME WITH REDUCED HARMONICS AND SIGNAL IMAGES

(71) Applicants: Lei Ding, Plano, TX (US); Rahmi Hezar, Allen, TX (US); Joonhoi Hur, Dallas, TX (US); Baher S. Haroun, Allen, TX (US)

(72) Inventors: Lei Ding, Plano, TX (US); Rahmi Hezar, Allen, TX (US); Joonhoi Hur, Dallas, TX (US); Baher S. Haroun, Allen, TX (US)

(73) Assignee: Texas Instruments Incorporated, Dallas, TX (US)

(21) Appl. No.: 13/421,567

(22) Filed: Mar. 15, 2012

(51) Int. Cl. H03K 7/08

(52) U.S. Cl. 332/109

(57) ABSTRACT

A method is provided. An input signal is received, and a noise-shaped signal is generated from the input signal. The noise-shaped signal is formed from a plurality of noise-shaping levels. A pulse stream is generated from the noise-shaped signal over a plurality of periods, where each period has a plurality of frames. The pulse stream also includes a plurality of pulse sets, where each pulse set is associated with at least one of the noise-shaping levels, and, for each pulse set having a total pulse width for its period that is less than its period and greater than zero, each pulse set includes at least one pulse in each frame for its period.

### TECHNICAL FIELD

The invention relates generally to a radio frequency (RF) amplifier and, more particularly, to a pulse width modulator (PWM) for an RF amplifier.

### BACKGROUND

Turning to FIGS. 1 and 2, an example of a PWM amplifier 100 can be seen. In operation, the PWM amplifier 100 receives input signal IN at the sigma-delta modulator (SDM) 102. Assuming that the SDM 102 uses oversampling, this SDM 102 can spread the total noise power over the oversampling frequency band (which is generally larger than the band-of-interest) so as to reduce in-band noise. Typically, the SDM 102 has a number of noise-shaping or output levels (i.e., 17 levels from −8 to +8) that are used to generate a noise-shaped signal. The noise-shaped signal is then applied to the digital PWM 104 so as to generate a pulse width modulated pulse stream that is generally comprised of PWM signals (each of which corresponds to a noise-shaped or output level). As shown in FIG. 2, the PWM signals (which are used to form the pulse stream) are uniformly distributed about the center of the PWM period. This pulse stream can then be applied to the amplification stage 106 (which can, for example, be comprised of a digital-to-analog converter (DAC) and amplifier (i.e., class AB) or a switching amplifier (i.e., class D)).

One problem with this amplifier 100 is the nonlinear nature of the digital PWM 104. Some of the in-band nonlinearity associated with the digital PWM 104 can be corrected using predistortion or feedback control, but signal images and nonlinear components can be created at high frequencies (as shown in FIG. 3). As a result of having this high frequency content, the amplification stage 106 should have high linearity; otherwise the high frequency content will fold in-band, limiting in-band linearity. Additionally, this high frequency content can unnecessarily use power. This high frequency content should also be attenuated by high-order analog filters in order to meet spectral requirements. Thus, there is a need for an improved PWM amplifier.

Some examples of conventional systems are: U.S. Pat. No. 7,209,064; U.S. Pat. No. 7,327,296; U.S. Pat. No. 7,425,853; U.S. Pat. No. 7,782,238; and U.S. Pat. No. 7,830,289.

### SUMMARY

An embodiment of the present invention, accordingly, an apparatus is provided. The apparatus comprises a noise shaping circuit having a plurality of output levels; and a pulse width modulator (PWM) that is coupled to the noise shaping circuit, wherein the PWM is configured to generate a plurality of PWM signals, wherein each PWM signal corresponds to at least one of the plurality of output levels, and wherein each PWM signal is configured to be output over a PWM period, and wherein the PWM period is configured to include a plurality of frames, and wherein the plurality of PWM signals includes a set of PWM signals having a total pulse width for each PWM period that is less than the PWM period and greater than zero, and wherein each PWM signal from the set of PWM signals includes at least one pulse in each frame when generated.

In accordance with an embodiment of the present invention, the noise shaping circuit is configured to be clocked by a first clock signal having a first frequency, and wherein the PWM is configured to be clocked by a second clock signal having a second frequency, and wherein the second frequency is N−1 times the first frequency, and wherein N is the number of output levels.

In accordance with an embodiment of the present invention, the noise shaping circuit further comprises a sigma-delta modulator (SDM).

In accordance with an embodiment of the present invention, each PWM signal is symmetrical about the center of the PWM period.

In accordance with an embodiment of the present invention, the PWM signal has two frames.

In accordance with an embodiment of the present invention, each PWM signal is asymmetrical about the center of the PWM period.

In accordance with an embodiment of the present invention, a method is provided. The method comprises receiving an input signal; generating a noise-shaped signal from the input signal, wherein the noise-shaped signal is formed from a plurality of noise-shaping levels; and generating a pulse stream from the noise-shaped signal over a plurality of periods, wherein each period has a plurality of frames, and wherein the pulse stream includes a plurality of pulse sets, wherein each pulse set is associated with at least one of the noise-shaping levels, and wherein, for each pulse set having a total pulse width for its period that is less than its period and greater than zero, each pulse set includes at least one pulse in each frame for its period.

In accordance with an embodiment of the present invention, the method further comprises generating a radio frequency (RF) signal from the pulse stream.

In accordance with an embodiment of the present invention, the step of generating the noise-shaped signal further comprises generating the noise-shaped signal from the input signal using sigma-delta modulation.

In accordance with an embodiment of the present invention, the step of generating the noise-shaped signal is performed at a first frequency, and wherein the step of generating the pulse stream is performed at a second frequency, and wherein the second frequency is N−1 times the first frequency, and wherein N is the number of noise-shaped levels.

In accordance with an embodiment of the present invention, each pulse set is symmetrical about the center of its period.

In accordance with an embodiment of the present invention, each period has two frames.

In accordance with an embodiment of the present invention, each pulse set is asymmetrical about the center of its period.

In accordance with an embodiment of the present invention, an apparatus is provided. The apparatus comprises a digital modulator; an SDM that is coupled to the digital modulator, wherein the SDM is clocked by a first clock signal having a first frequency, and wherein the SDM has a plurality of noise-shaped levels; a PWM that is coupled to the SDM, wherein the PWM is clocked by a second clock having a second frequency so as to have a PWM period with a plurality of frames, and wherein the PWM is configured to generate a PWM signal for each noise-shaped level such that, for each PWM signal having a total pulse width for the PWM period that is less than the PWM period and greater than zero, there is at least one pulse in each frame; and an amplifier that is coupled to the PWM.

In accordance with an embodiment of the present invention, the apparatus further comprises a filter that is coupled to the amplifier.

In accordance with an embodiment of the present invention, the second frequency is N−1 times the first frequency, and wherein N is the number of noise-shaped levels.

In accordance with an embodiment of the present invention, the PWM further comprises a lookup table that stores the PWM signal for each noise-shaped level.

In accordance with an embodiment of the present invention, the PWM signal for each noise is selected to be symmetrical about the center of the PWM period.

In accordance with an embodiment of the present invention, the PWM signal for each noise is selected to be asymmetrical about the center of the PWM period.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated by those skilled in the art that the conception and the specific embodiment disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is a diagram of an example of a conventional PWM amplifier;

FIG. 2 is a diagram depicting the PWM signals used by the digital PWM of FIG. 1;

FIG. 3 is a log-scale plots depicting signal images and nonlinear components created as a result of the nonlinear behavior of the digital PWM of FIG. 1;

FIG. 4 is a diagram of an example of a PWM amplifier and load in accordance with an embodiment of the present invention;

FIG. 5 is a diagram depicting PWM signals that are symmetrical about the center of the PWM period used by digital PWM of FIG. 4;

FIG. 6 is a log-scale plots depicting signal images and nonlinear components created as a result of the nonlinear behavior of the digital PWM of FIG. 4 that is employing the PWM signals of FIG. 5;

FIGS. 7A to 7D are diagrams depicting alternative PWM signals that are symmetrical about the center of the PWM period used by digital PWM of FIG. 4;

FIG. 8 is a diagram depicting PWM signals that are asymmetrical about the center of the PWM period used by digital PWM of FIGS. 4; and

FIG. 9 is a log-scale plots depicting signal images and nonlinear components created as a result of the nonlinear behavior of the digital PWM of FIG. 4 that is employing the PWM signals of FIG. 8.

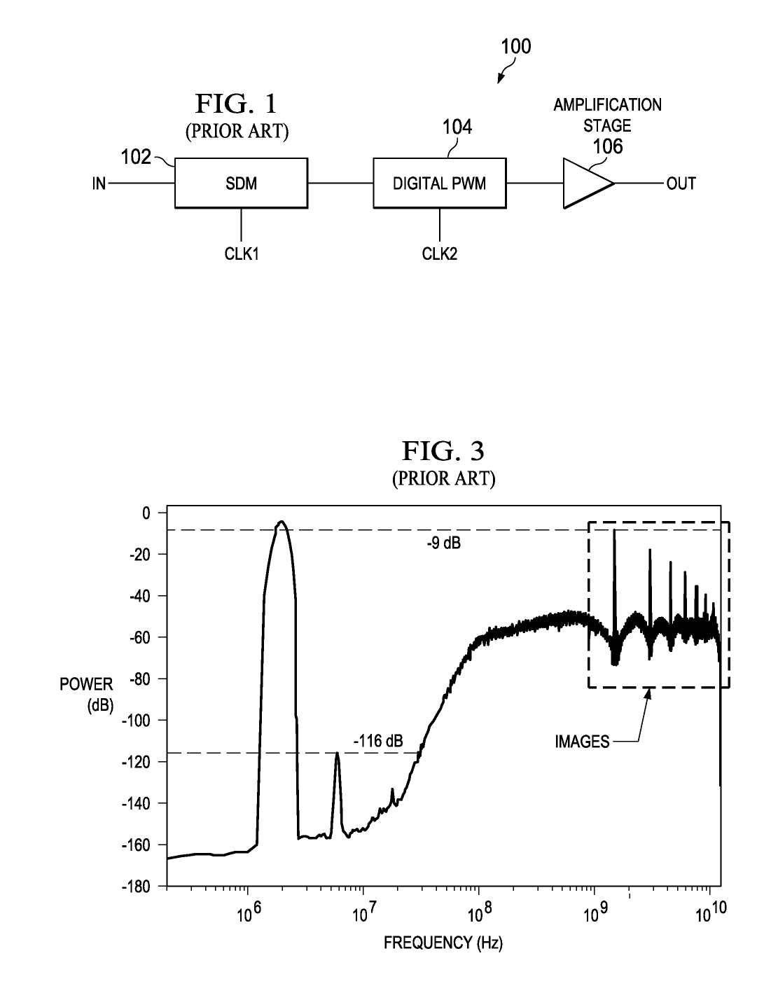

### DETAILED DESCRIPTION

Refer now to the drawings wherein depicted elements are, for the sake of clarity, not necessarily shown to scale and wherein like or similar elements are designated by the same reference numeral through the several views.

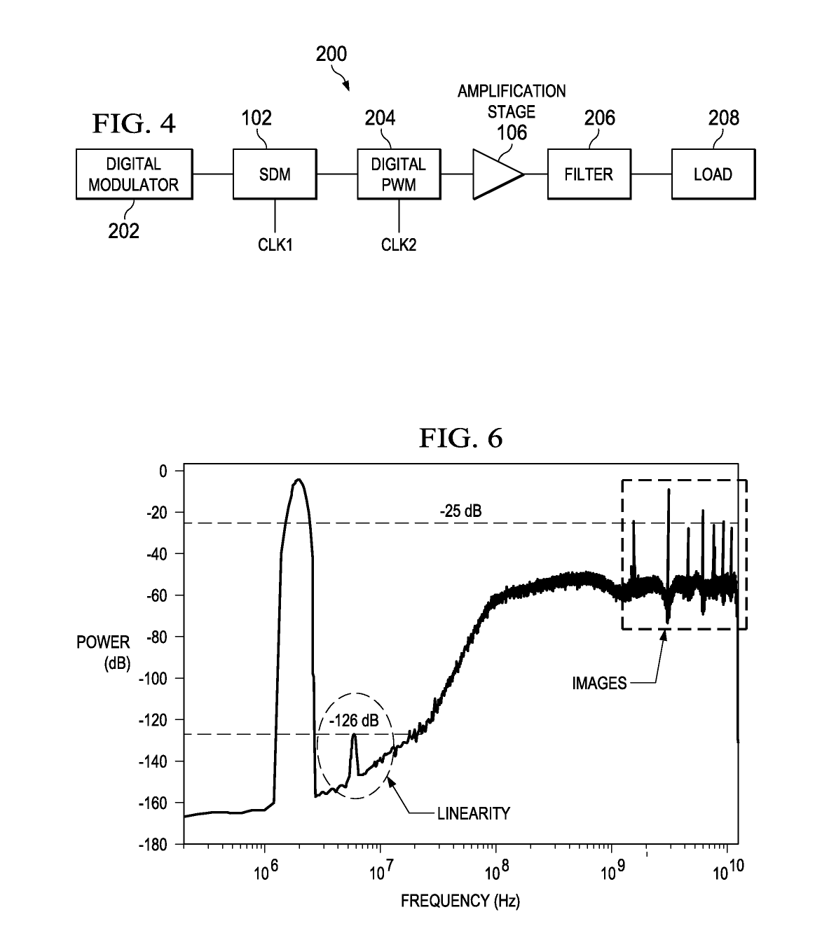

Turning to FIG. 4, an example of a PWM amplifier 200 can be seen. In this example, a digital modulator 202 provides a signal to SDM 102 (which is generally clocked by clock signal CLK1 having a frequency F_{S} and which, for example, can have 17 noise-shaped or output levels ranging from −8 to +8). The SDM 102 modifies the signal from the digital modulator 202 to generate a noise-shaped signal for the digital PWM 204 (which is generally clocked by clock signal CLK2 having a frequency 16F_{S}). Typically, the frequency of clock signal CLK2 is related to the number of output levels of SDM 102 (i.e., 17) and the frequency of clock signal CLK1. Amplification stage 106 can then generate an RF signal from the pulse stream output from the digital PWM 204, which can be filtered by filter 206 and applied to load 208 (i.e., antenna).

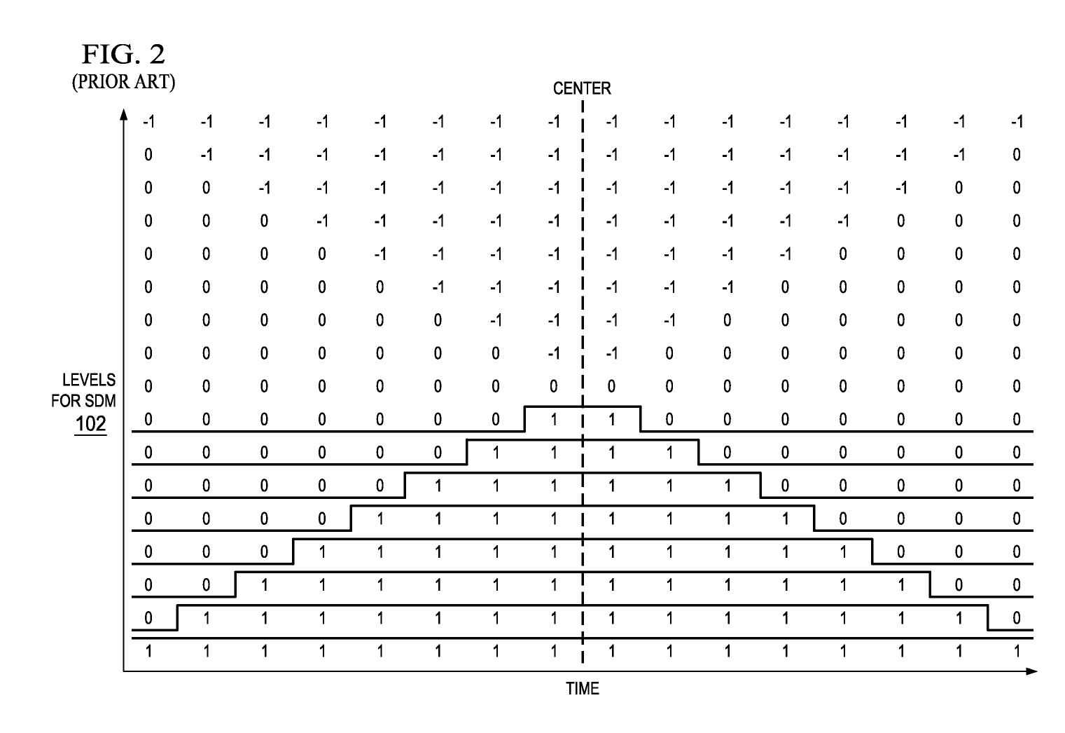

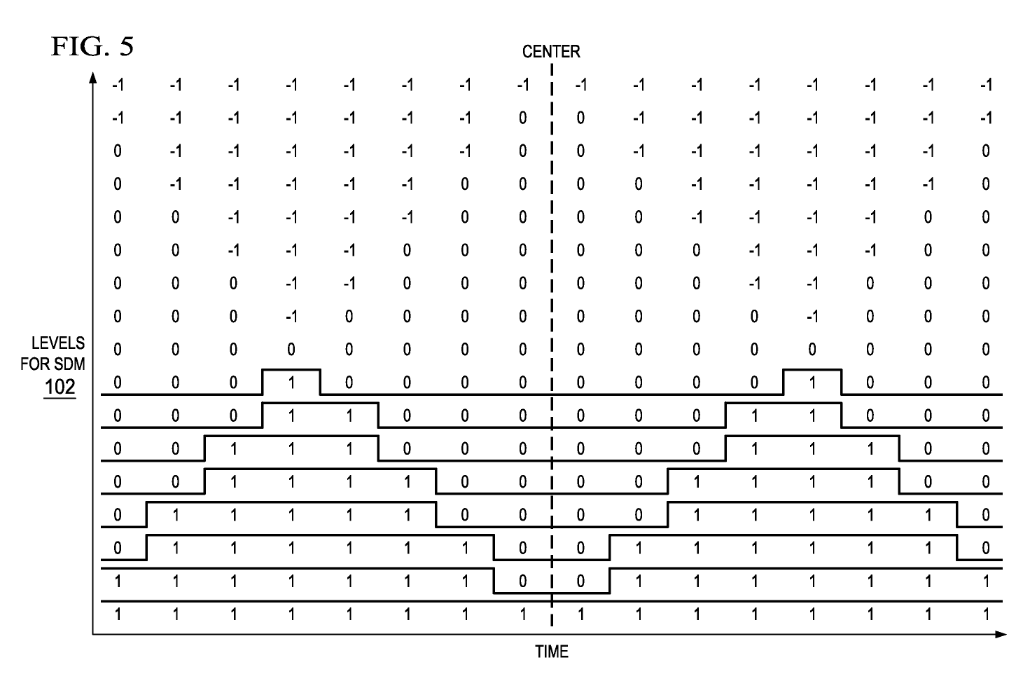

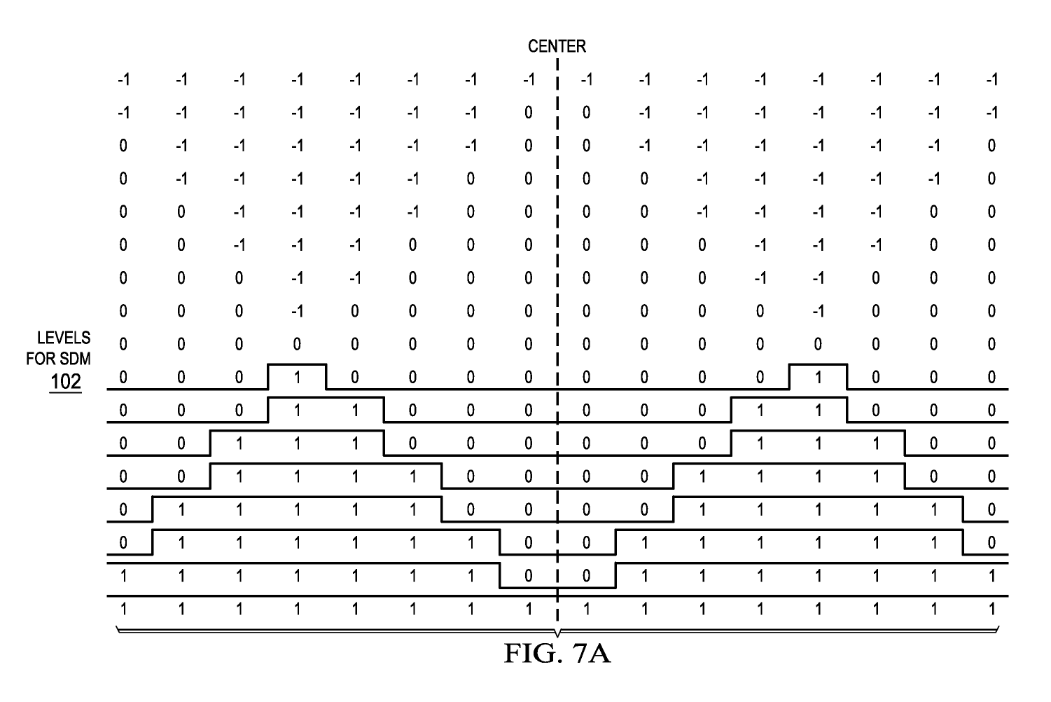

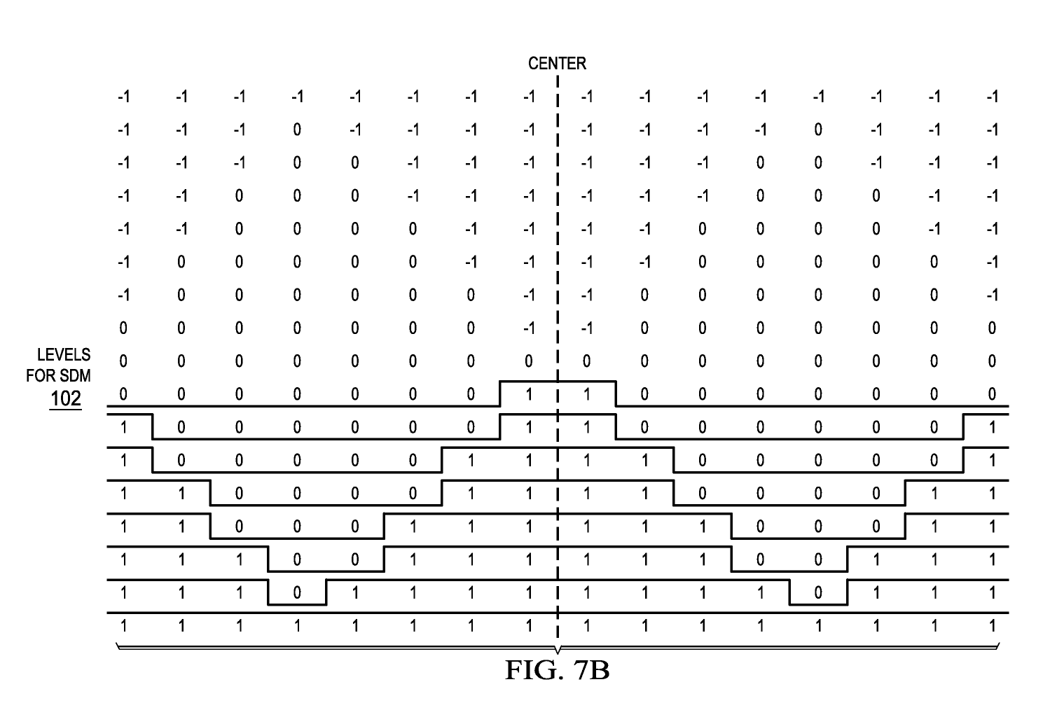

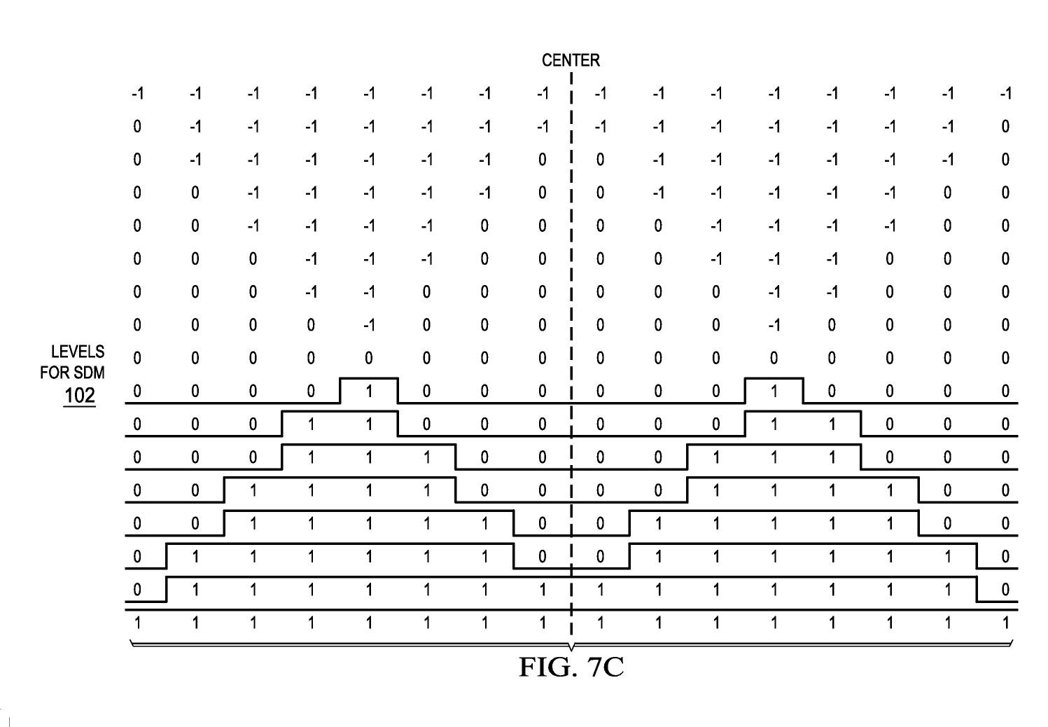

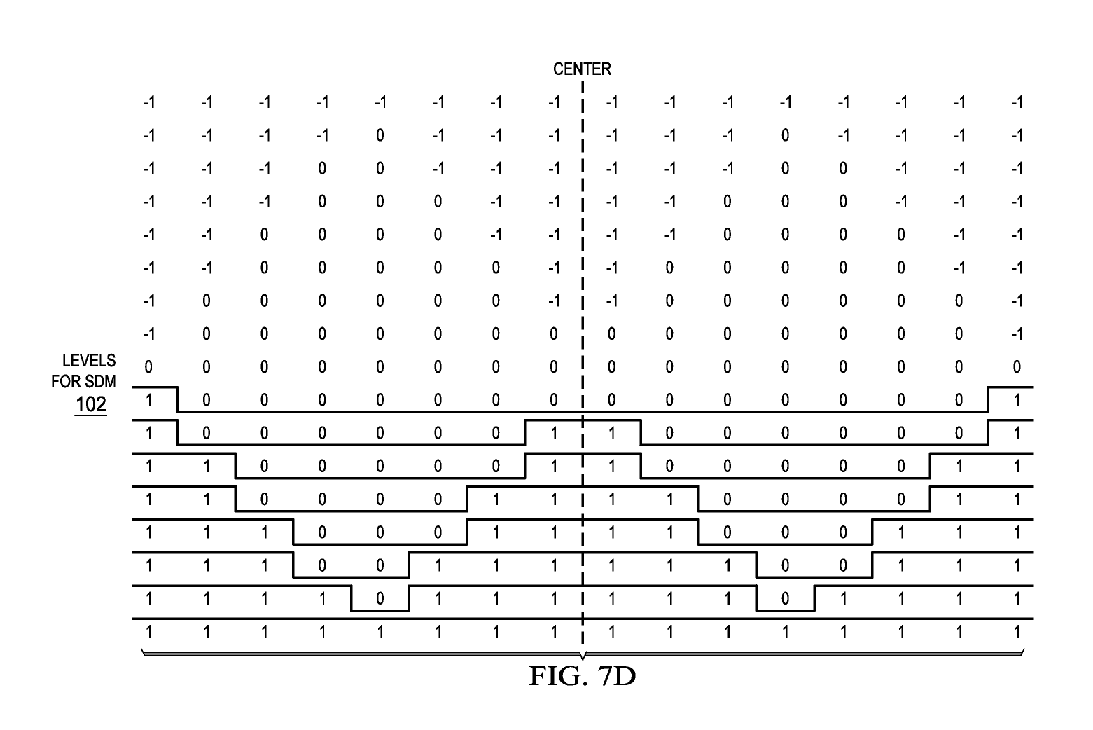

One difference between amplifiers 100 and 200, though, lies in the PWM signals employed by digital PWM 204. In FIG. 5, an example of a set of PWM signals that correspond to the output levels from SDM 102 can be seen (which can, for example, be stored in a lookup table within PWM 204). As shown in FIG. 5, the PWM period is divided into two frames, and the PWM signals are symmetric about the center of the PWM period. But, these PWM signals are not uniformly distributed about the center as the PWM signals shown in FIG. 2; instead, for each PWM signal that has a total pulse width that is less than the entire PWM period and greater than zero (which would generally include, for this example, all of the PWM signals except for output levels −8, +8 and 0), there is a pulse in each frame. The total pulse width for each PWM signal shown in the example of FIG. 5, though, is generally equal to the total pulse width for the corresponding PWM signal shown in FIG. 2. By doing this, close-in harmonics and signal images can be attenuated as shown in the FIG. 6, while also increasing linearity (i.e., from −116 dB to −126 dB). Other alternative PWM signals (which are shown to be symmetric about the center of the PWM period that has two frames) can be seen in FIGS. 7A to 7D.

A reason for these improvements can be seen with a spectral analysis. Looking, for example, to the PWM signal that corresponds to the +1 output level in FIG. 5 (which, as shown, is “0001000000001000”), the discrete-time Fourier transform for this PWM signal is:

$$\begin{matrix}Y ( PWM 1 ) = {\sum }_{n = 0}^{N - 1} x ( n ) {e}^{- i ω n} \\ = {e}^{- 3 ω i } + {e}^{- 12 ω i} \\ = {e}^{- 7.5 ω i} ( {e}^{4.5 ω i} + {e}^{- 4.5 ω i} ) \\ = 2 {e}^{- 7.5 ω i} cos ( 4.5 ω )\end{matrix} \qquad ( 1 )$$

Now, looking, for example, to the PWM signal that corresponds to the +2 output level in FIG. 5 (which, as shown, is “0001100000011000”), the discrete-time Fourier transform for this PWM signal is:

$$\begin{matrix}Y ( PWM 2 ) = {\sum }_{n = 0}^{N - 1} x ( n ) {e}^{- i ω n} \\ = {e}^{- 3 ω i} + {e}^{- 4 ω i} + {e}^{- 11 ω i} + {e}^{- 12 ω i} \\ = {e}^{- 7.5 ωi} ( {e}^{4.5 ω i} + {e}^{3.5 ωi} + {e}^{- 3.5 ωi} + {e}^{- 4.5 ω i} ) \\ = 2 {e}^{- 7.5 ωi} ( cos ( 4.5 ω ) + cos ( 3.5 ω ) ) \\ = 4 {e}^{- 7.5 ω i} cos ( 4 ω ) cos ( 0.5 ω )\end{matrix} \qquad ( 2 )$$

As can be seen from equations (1) and (2), both PWM signals have a common phase term (i.e., e^{-7.5ωi}). This phase term and the corresponding magnitude response allow for more linearity at low frequency (i.e., 0 to F_{S}). Additionally, the energy at frequency F_{S} (which is generally the frequency of clock signal CLK1) is lower compared to the PWM signals of FIG. 2.

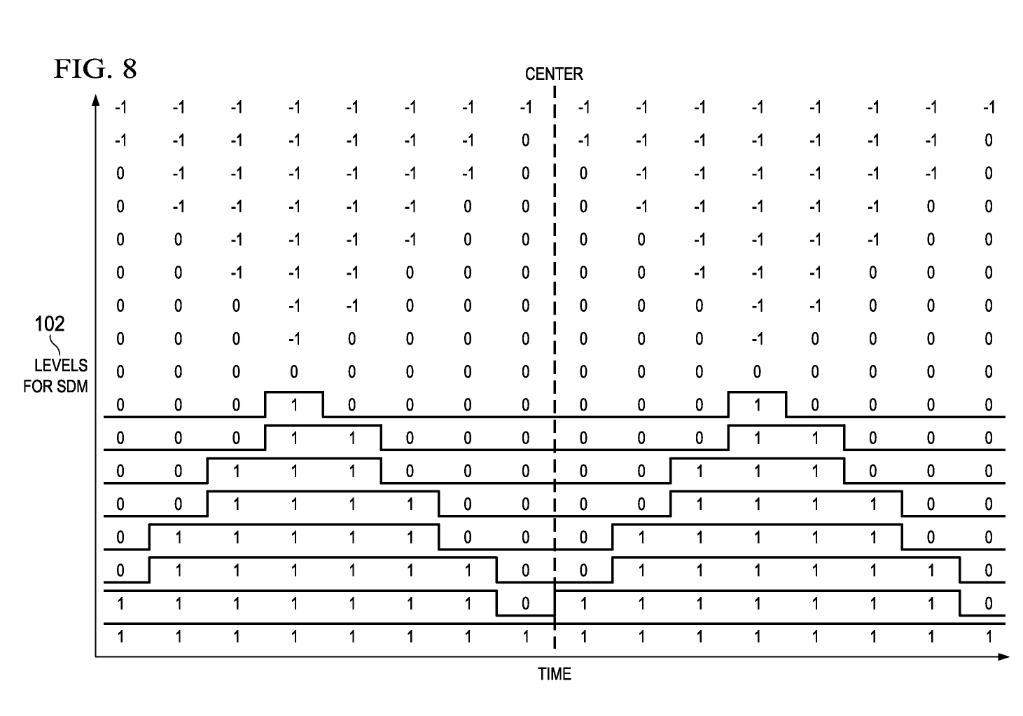

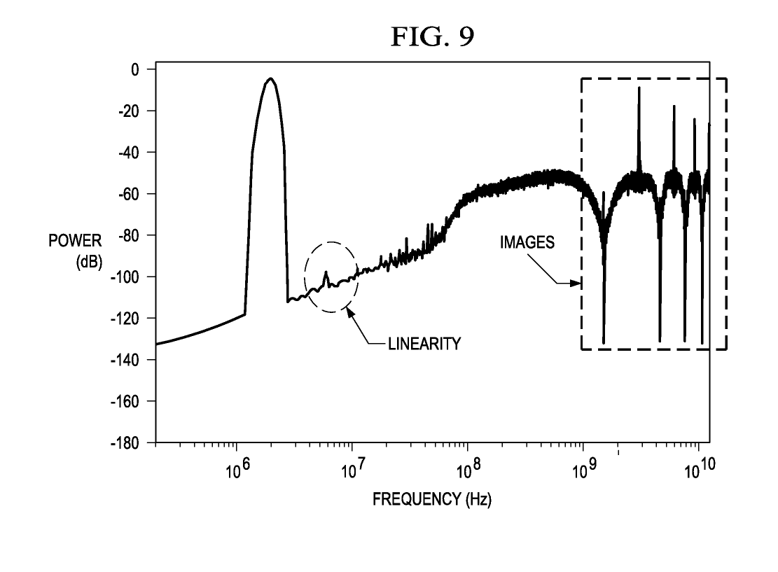

As another alternative (an example of which can be seen in FIG. 8), the PWM signals may be asymmetric about the center of the PWM period. As shown in the example of FIG. 8, the PWM period is divided into two frames (similar to FIGS. 5 and 7A to 7D), and, for each PWM signal that has a total pulse width that is less than the entire PWM period and greater than zero (which would generally include, for this example, all of the PWM signals except for output levels −8, +8 and 0), there is a pulse in each frame (also similar to FIGS. 5 and 7A to 7D). Yet, the pulses are “off center.” This allows close-in harmonics and signal images to be attenuated as shown in the FIG. 9, where there is better response for the signal images compared to FIG. 6. However, the in-band linearity is degraded, meaning that there is a tradeoff between response for the signal images and in-band linearity. Other alternative PWM signals that are asymmetric about the center of the PWM (similar to those shown symmetric PWM signals seen in FIGS. 7A to 7D) can also be employed, but have been omitted for the sake of simplicity of illustration.

Similar to FIG. 5, a reason for the improvements associated with FIG. 8 can be seen in a spectral analysis. Looking, for example, to the PWM signal that corresponds to the +1 output level in FIG. 8 (which, as shown, is “0001000000010000”), the discrete-time Fourier transform for this PWM signal is:

$$\begin{matrix}Y ( PWM 1 ) = {\sum }_{n = 0}^{N - 1} x ( n ) {e}^{- iω n} \\ = {e}^{- 3 ω i} + {e}^{- 11 ωi} \\ = {e}^{- 7 ωi} ( {e}^{4 ω i} + {e}^{- 4 ω i} ) \\ = 2 {e}^{- 7 ω i} cos ( 4 ω )\end{matrix} \qquad ( 3 )$$

Now, looking, for example, to the PWM signal that corresponds to the +2 output level in FIG. 8 (which, as shown, is “0001100000011000”), the discrete-time Fourier transform for this PWM signal is:

$$\begin{matrix}Y ( PWM 2 ) = {\sum }_{n = 0}^{N - 1} x ( n ) {e}^{- i ω n} \\ = {e}^{- 3 ω i} + {e}^{- 4 ω i} + {e}^{- 11 ω i} + {e}^{- 12 ω i} \\ = {e}^{- 7.5 ω i} ( {e}^{4.5 ω i} + {e}^{3.5 ωi} + {e}^{- 3.5 ω i} + {e}^{- 4.5 ω i} ) \\ = 2 {e}^{- 7.5 ωi} ( cos ( 4.5 ω ) + cos ( 3.5 ω ) ) \\ = 4 {e}^{- 7.5 ω i} cos ( 4 ω ) cos ( 0.5 ω )\end{matrix} \qquad ( 4 )$$

As can be seen from equations (3) and (4), both PWM signals have a common frequency term (i.e., 4ω), but different phase terms (i.e., e^{-7ωi} and e^{-7.5ωi}). Thus, there is less linearity compared to the PWM signals of FIG. 5. Additionally, with the PWM signals of FIG. 9, all of the codes or PWM signals have nulls at frequency F_{S} (which is generally the frequency of clock signal CLK1) that reduces harmonics and images compared to the PWM signals of FIGS. 2 and 6. Moreover, these PWM schemes (both symmetric and asymmetric) can be employed when the pulse stream (use of PWM signals) is mixed with a carrier so as to be located at a carrier frequency as opposed to direct current (DC).

Having thus described the present invention by reference to certain of its preferred embodiments, it is noted that the embodiments disclosed are illustrative rather than limiting in nature and that a wide range of variations, modifications, changes, and substitutions are contemplated in the foregoing disclosure and, in some instances, some features of the present invention may be employed without a corresponding use of the other features. Accordingly, it is appropriate that the appended claims be construed broadly and in a manner consistent with the scope of the invention.

1. An apparatus comprising:
a noise shaping circuit having a plurality of output levels; and
a pulse width modulator (PWM) that is coupled to the noise shaping circuit, wherein the PWM is configured to generate a plurality of PWM signals, wherein each PWM signal corresponds to at least one of the plurality of output levels, and wherein each PWM signal is configured to be output over a PWM period, and wherein the PWM period is configured to include a plurality of frames, and wherein the plurality of PWM signals include a set of PWM signals having a total pulse width for each PWM period that is less than the PWM period and greater than zero, and wherein each PWM signal from the set of PWM signals includes at least one pulse in each frame when generated.

2. The apparatus of claim 1, wherein the noise shaping circuit is configured to be clocked by a first clock signal having a first frequency, and wherein the PWM is configured to be clocked by a second clock signal having a second frequency, and wherein the second frequency is N−1 times the first frequency, and wherein N is the number of output levels.

3. The apparatus of claim 2, wherein the noise shaping circuit further comprises a sigma-delta modulator (SDM).

4. The apparatus of claim 3, wherein each PWM signal is symmetrical about the center of the PWM period.

5. The apparatus of claim 4, wherein the PWM signal has two frames.

6. The apparatus of claim 3, wherein each PWM signal is asymmetrical about the center of the PWM period.

7. The apparatus of claim 6, wherein the PWM signal has two frames.

8. A method comprising:
receiving input signal;
generating a noise-shaped signal from the input signal, wherein the noise-shaped signal is formed from a plurality of noise-shaping levels; and
generating a pulse stream from the noise-shaped signal over a plurality of periods, wherein each period has a plurality of frames, and wherein the pulse stream includes a plurality of pulse sets, wherein each pulse set is associated with at least one of the noise-shaping levels, and wherein, for each pulse set having a total pulse width for its period that is less than its period and greater than zero, each pulse set includes at least one pulse in each frame for its period.

9. The method of claim 8, wherein the method further comprises generating a radio frequency (RF) signal from the pulse stream.

10. The method of claim 9, wherein the step of generating the noise-shaped signal further comprises generating the noise-shaped signal from the input signal using sigma-delta modulation.

11. The method of claim 10, wherein the step of generating the noise-shaped signal is performed at a first frequency, and wherein the step of generating the pulse stream is performed at a second frequency, and wherein the second frequency is N−1 times the first frequency, and wherein N is the number of noise-shaped levels.

12. The method of claim 11, wherein each pulse set is symmetrical about the center of its period.

13. The apparatus of claim 12, wherein each period has two frames.

14. The apparatus of claim 11, wherein each pulse set is asymmetrical about the center of its period.

15. The apparatus of claim 14, wherein each period has two frames.

16. An apparatus comprising:
a digital modulator;
an SDM that is coupled to the digital modulator, wherein the SDM is clocked by a first clock signal having a first frequency, and wherein the SDM has a plurality of noise-shaped levels;
a PWM that is coupled to the SDM, wherein the PWM is clocked by a second clock having a second frequency so as to have a PWM period with a plurality of frames, and wherein the PWM is configured to generate a PWM signal for each noise-shaped level such that, for each PWM signal having a total pulse width for the PWM period that is less than the PWM period and greater than zero, there is at least one pulse in each frame; and
an amplifier that is coupled to the PWM.

17. The apparatus of claim 16, wherein the apparatus further comprises a filter that is coupled to the amplifier.

18. The apparatus of claim 17, wherein the second frequency is N−1 times the first frequency, and wherein N is the number of noise-shaped levels.

19. The apparatus of claim 18, wherein the PWM further comprises a lookup table that stores the PWM signal for each noise-shaped level.

20. The apparatus of claim 19, wherein the PWM signal for each noise is selected to be symmetrical about the center of the PWM period.

21. The apparatus of claim 20, wherein the PWM period has two frames.

22. The apparatus of claim 19, wherein the PWM signal for each noise is selected to be asymmetrical about the center of the PWM period.

23. The apparatus of claim 22, wherein the PWM period has two frames.
